(19) United States
(12) Patent Application Publication
(10) Pub. No.: US 2007/0004049 A1
(43) Pub. Date: Jan. 4, 2007

(54) Semiconductor device having ferroelectric film as gate insulating film and manufacturing method thereof

(76) Inventors: Hayato Nasu, Soka-shi (JP); Takamasa Usui, Tokyo (JP); Hideki Shibata, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/476,596

(22) Filed: Jun. 29, 2006

(30) Foreign Application Priority Data
Jun. 30, 2005 (JP) 2005-192652

(51) Int. Cl. H01L 21/00; H01L 29/94; H01L 21/4763

(52) U.S. Cl. 438/3; 438/622; 257/295

(57) ABSTRACT

A semiconductor device includes a gate insulating film which at least includes a first insulating film formed on the main surface of a semiconductor substrate and a first ferroelectric film formed on the first insulating film, containing a compound of a preset metal element and a constituent element of the first insulating film as a main component and having a dielectric constant larger than that of the first insulating film, a gate electrode formed on the gate insulating film and containing one of Cu and a material containing Cu as a main component, and source and drain regions separately formed in the semiconductor substrate to sandwich the gate electrode.

### CROSS-REFERENCE TO RELATED APPLICATIONS

This application is based upon and claims the benefit of priority from prior Japanese Patent Application No. 2005-192652, filed Jun. 30, 2005, the entire contents of which are incorporated herein by reference.

### BACKGROUND OF THE INVENTION

1. Field of the Invention

This invention relates to a semiconductor device and a manufacturing method thereof and is applied to a gate insulating film or the like of a MOSFET (Metal Oxide Semiconductor Field Effect Transistor), for example. Further, this invention is not limited to the above case and is applied to memory cell transistors of a nonvolatile semiconductor memory such as a flash memory and a manufacturing method thereof, for example.

2. Description of the Related Art

Recently, it is more strongly required to miniaturize MOSFETs in order to realize high performance (for example, switching voltage subjected to a less variation, the operation under high frequencies or the like) of an LSI (Large Scale Integrated circuit).

In order to meet the requirement for miniaturization, it is necessary and indispensable to use a gate insulating film having a ferroelectric film (so-called high-k film) which are formed thin and uniform to attain stable and large electrostatic capacitance.

However, the conventional ferroelectric film is formed of a ferroelectric material such as SiN (silicon nitride) by use of a film formation method, for example, a sputtering method or CVD (Chemical Vapor Deposition) method. Therefore, it is impossible to attain uniformity in an extremely thin region of less than 10 nm and a thin and uniform ferroelectric film cannot be formed (for example, refer to Jpn. Pat. Appln KOKAI Publication No. 2003-258242). As a result, a gate insulating film having a desired ferroelectric film (high-k film) cannot be formed and it is disadvantageous in miniaturizing the MOSFET.

### BRIEF SUMMARY OF THE INVENTION

A semiconductor device according to an aspect of the present invention comprises a gate insulating film which at least includes a first insulating film formed in the main surface of a semiconductor substrate and a first ferroelectric film formed on the first insulating film, containing a compound of a preset metal element and a constituent element of the first insulating film as a main component and having a dielectric constant larger than that of the first insulating film, a gate electrode formed on the gate insulating film and formed of one of Cu and a material containing Cu as a main component, and source and drain regions separately formed in the semiconductor substrate to sandwich the gate electrode.

A semiconductor device according to another aspect of the present invention comprises a gate insulating film which at least includes a first insulating film formed in the main surface of a semiconductor substrate and a first ferroelectric film formed on the first insulating film, containing a compound of a preset metal element and a constituent element of the first insulating film as a main component and having a dielectric constant larger than that of the first insulating film, a floating electrode formed on the gate insulating film and formed of one of Cu and a material containing Cu as a main component, source and drain regions separately formed in the semiconductor substrate to sandwich the floating electrode, a gate-gate insulating film which at least includes a second insulating film formed on the floating electrode and a second ferroelectric film formed on the second insulating film, containing a compound of a preset metal element and a constituent element of the second insulating film as a main component and having a dielectric constant larger than that of the second insulating film, and a control electrode formed on the gate-gate insulating film and formed of one of Cu and a material containing Cu as a main component.

A method of manufacturing a semiconductor device according to a further aspect of the present invention comprises forming a first insulating film in the main surface of a semiconductor substrate, forming a dummy gate on the insulating film, doping impurity into the semiconductor substrate to form source and drain regions with the dummy gate used as a mask, forming spacer insulating films on side walls of the dummy gate, removing the dummy gate to form an opening which exposes the surface of the first insulating film, forming an electrode layer which contains a preset metal element and contains Cu as a main component in the opening, and performing heat treatment to form a first ferroelectric film which contains a compound of the preset metal element and a constituent element of the first insulating film as a main component and having a dielectric constant larger than that of the first insulating film on an interface between the first insulating film and the electrode layer in a self-alignment fashion.

### BRIEF DESCRIPTION OF THE SEVERAL VIEWS OF THE DRAWING

FIG. 1 is a cross sectional view showing a semiconductor device according to a first embodiment of this invention;

FIG. 2 is a view showing a microphotograph of a cross sectional TEM image of a portion near a channel region shown in FIG. 1;

FIG. 3 is a cross sectional view showing one manufacturing step of the semiconductor device according to the first embodiment of this invention;

FIG. 4 is a cross sectional view showing one manufacturing step of the semiconductor device according to the first embodiment of this invention;

FIG. 5 is a cross sectional view showing one manufacturing step of the semiconductor device according to the first embodiment of this invention;

FIG. 6 is a cross sectional view showing one manufacturing step of the semiconductor device according to the first embodiment of this invention;

FIG. 7 is a cross sectional view showing one manufacturing step of the semiconductor device according to the first embodiment of this invention;

FIG. 8 is a cross sectional view showing one manufacturing step of the semiconductor device according to the first embodiment of this invention;

FIG. 9 is a cross sectional view showing one manufacturing step of the semiconductor device according to the first embodiment of this invention;

FIG. 10 is a cross sectional view showing one manufacturing step of the semiconductor device according to the first embodiment of this invention;

FIG. 11 is a cross sectional view showing one manufacturing step of the semiconductor device according to the first embodiment of this invention;

FIG. 12 is a cross sectional view showing one manufacturing step of the semiconductor device according to the first embodiment of this invention;

FIG. 13 is a cross sectional view showing a semiconductor device according to a second embodiment of this invention;

FIG. 14 is a cross sectional view showing one manufacturing step of the semiconductor device according to the second embodiment of this invention;

FIG. 15 is a cross sectional view showing one manufacturing step of the semiconductor device according to the second embodiment of this invention;

FIG. 16 is a cross sectional view showing one manufacturing step of the semiconductor device according to the second embodiment of this invention;

FIG. 17 is a cross sectional view showing one manufacturing step of the semiconductor device according to the second embodiment of this invention;

FIG. 18 is a cross sectional view showing one manufacturing step of the semiconductor device according to the second embodiment of this invention;

FIG. 19 is a cross sectional view showing one manufacturing step of the semiconductor device according to the second embodiment of this invention;

FIG. 20 is a cross sectional view showing one manufacturing step of the semiconductor device according to the second embodiment of this invention;

FIG. 21 is a cross sectional view showing a portion near the channel region of a semiconductor device according to a modification 1 of the embodiment of this invention;

FIG. 22 is a cross sectional view showing a portion near the channel region of a semiconductor device according to a modification 2 of the embodiment of this invention;

FIG. 23 is a cross sectional view showing a portion near the channel region of a semiconductor device according to a modification 3 of the embodiment of this invention;

FIG. 24 is a cross sectional view showing a semiconductor device according to a third embodiment of this invention;

FIG. 25 is a cross sectional view showing one manufacturing step of the semiconductor device according to the third embodiment of this invention;

FIG. 26 is a cross sectional view showing one manufacturing step of the semiconductor device according to the third embodiment of this invention;

FIG. 27 is a cross sectional view showing one manufacturing step of the semiconductor device according to the third embodiment of this invention;

FIG. 28 is a cross sectional view showing a semiconductor device according to a fourth embodiment of this invention;

FIG. 29 is a cross sectional view showing one manufacturing step of the semiconductor device according to the fourth embodiment of this invention;

FIG. 30 is a cross sectional view showing one manufacturing step of the semiconductor device according to the fourth embodiment of this invention;

FIG. 31 is a cross sectional view showing one manufacturing step of the semiconductor device according to the fourth embodiment of this invention; and

FIG. 32 is a cross sectional view showing one manufacturing step of the semiconductor device according to the fourth embodiment of this invention.

### DETAILED DESCRIPTION OF THE INVENTION

There will now be described embodiments of this invention with reference to the accompanying drawings. In this explanation, common reference symbols are attached to like portions throughout the drawings.

### First Embodiment

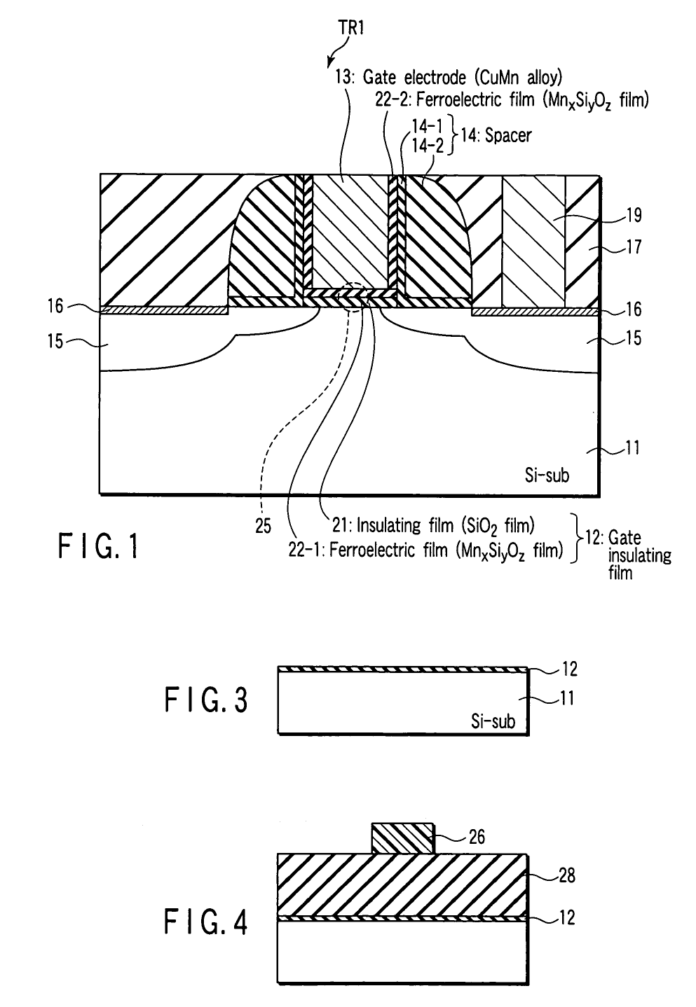

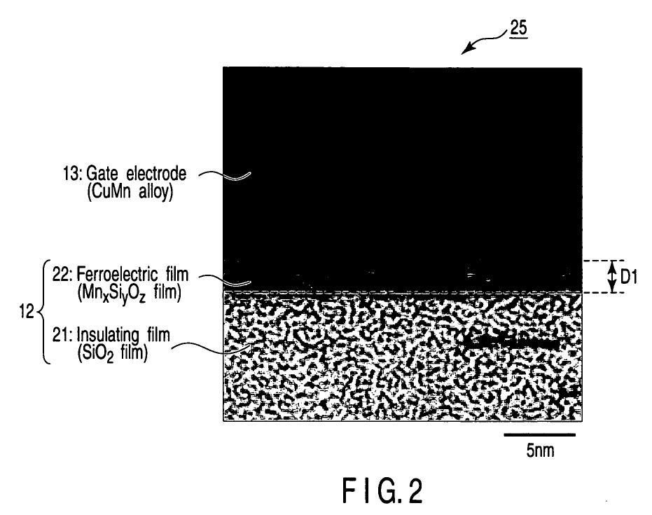

First, a semiconductor device according to a first embodiment of this invention is explained with reference to FIGS. 1 and 2. The embodiment relates to a damascene metal gate structure in which a CuMn alloy containing Cu (copper) as a main component (that is, 50% or more) is applied to the gate electrode of a MOSFET (Metal Oxide Semiconductor Field Effect Transistor). FIG. 1 is a cross sectional view showing the semiconductor device according to the first embodiment. FIG. 2 is a view showing a microphotograph of a cross sectional TEM image of a portion near a portion indicated by broken lines 25 (near the channel region) in FIG. 1.

As shown in FIG. 1, an insulating gate type field effect transistor TR1 is formed in the main surface of a silicon substrate 11. The transistor TR1 includes a gate insulating film 12 formed on the silicon substrate 11, a gate electrode 13 formed on the gate insulating film 12, spacers 14 formed on the side walls of the gate electrode 13, source/drain regions 15 separately formed in the substrate 11 to sandwich the gate electrode 13, silicide layers 16 formed on the source/drain regions 15 and a contact wiring 19 formed on the source/drain regions 15 via an inter-level insulating film 17.

The gate insulating film 12 includes an insulating film 21 formed on the main surface of the substrate 11 and a ferroelectric film 22-1 formed on the insulating film 21 and containing a compound of a preset metal element and a constituent element of the insulating film 21 as a main component.

In this example, the insulating film 21 is formed of an SiO₂ (silicon oxide) film. In this example, the ferroelectric film 22-1 is formed of an MnₓSi_{y}O_{z} (manganese silicon oxide) film. The composition of the MnₓSi_{y}O_{z} film is specifically expressed by 1:1:3 to 1:3:5 as x:y:z of MnₓSi_{y}O_{z}.

The gate electrode 13 is formed of Cu or a CuMn (copper-manganese) alloy containing Cu as a main component (that is, 50% or more).

The spacer 14 is configured by a spacer insulating film 14-1 formed on the side wall of the gate electrode 13 above the substrate 11 and a spacer insulating film 14-2 formed on the spacer insulating film 14-1.

For example, the spacer insulating film 14-1 is formed of a TEOS (Tetraethylorthosilicate) film or the like. For example, the spacer insulating film 14-2 is formed of an SiN film or the like.

As shown in FIG. 2, the ferroelectric film 22-1 on the insulating film 21 has a dielectric constant larger than that of the insulating film 21 and is formed of a thin and uniform MnₓSi_{y}O_{z} film. The film thickness D1 of the ferroelectric film 22-1 is approximately 2 nm to 3 nm. Therefore, it functions as a preferable gate insulating film together with the insulating film 21.

The ferroelectric films 22-1, 22-2 are formed on the interface between the gate electrode 13 and the insulating film 21 and the interface between the gate electrode 13 and the spacer insulating film 14-1. In this case, the ferroelectric films 22-1, 22-2 function as barriers which prevent Cu elements in the gate electrode 13 from being diffused.

The ferroelectric film 22-1 contains a compound of a preset metal element α and a constituent element of the insulating film 21 as a main component and is formed in a self-alignment fashion. The ferroelectric film 22-2 has a dielectric constant larger than that of the spacer insulating film 14-1, contains a compound of a preset metal element α and a constituent element of the spacer insulating film 14-1 as a main component and is formed in a self-alignment fashion.

The preset metal element α is not limited to Mn as in the present embodiment and may be an element selected from a group consisting of Nb, Zr, Cr, V, Y, Tc and Re. Each of the above metal elements α is a metal element which has a diffusion speed higher than Cu in a layer containing Cu and tends to more easily react with oxygen than Cu to form a thermally stabilized oxide.

The insulating film 21 and spacer insulating film 14-1 can contain O and at least one element selected from a group consisting of Si, C and F. As a specific material, for example, SiO₂, SiOₓC_{y}, SiOₓC_{y} H_{z}, SiOₓF_{y} and the like can be provided.

Further, the ferroelectric films 22-1, 22-2 can contain a material selected from a group consisting of αₓO_{y}, αₓSi_{y}O_{z}, αₓC_{y}O_{z} and αₓF_{y}O_{z} as a main component. In this case, α indicates the preset metal element α.

<Manufacturing Method>

Next, a manufacturing method of the semiconductor device according to the present embodiment is explained with reference to FIGS. 3 to 12 by taking the semiconductor device shown in FIGS. 1 and 2 as an example.

First, as shown in FIG. 3, a silicon substrate 11 is heated by use of a thermal oxidation method, for example, to form a silicon oxide film (insulating film) 12 on the main surface of the substrate 11.

Then, as shown in FIG. 4, a polysilicon film 28 is formed on the silicon oxide film 12 by use of a CVD method, for example. After this, photoresist 26 is coated on the polysilicon film 28 and the thus formed photoresist film 26 is subjected to the exposing and developing processes to form an opening which exposes the polysilicon film 28 in a region corresponding to the gate electrode.

Then, as shown in FIG. 5, an anisotropic etching process such as an RIE (Reactive Ion Etching) process, for example, is performed to etch a portion which reaches the surface of the substrate 11 while the photoresist film 26 having the opening is used as a mask. Thus, a dummy gate 29 is formed.

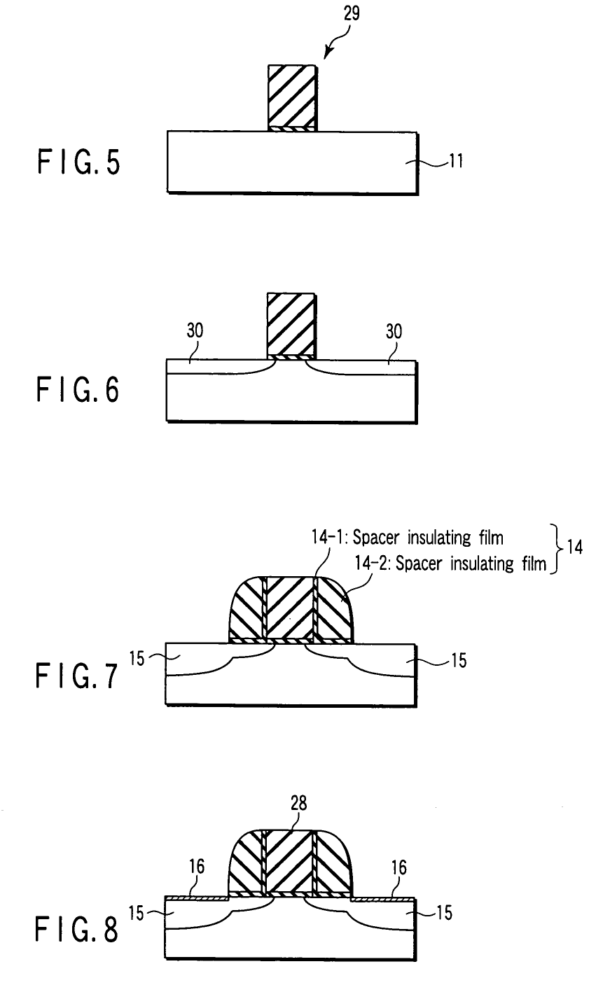

Next, as shown in FIG. 6, an impurity of a conductivity type different from that of the substrate 11, for example, boron (B) or phosphorus (P) is doped into the substrate 11 by use of an ion-implantation method, for example, with the dummy gate 29 used as a mask. After this, the substrate 11 is heated to thermally diffuse the doped impurity to form LDDs 30.

Then, as shown in FIG. 7, a TEOS film is formed along the substrate 11 and dummy gate 29 by use of the CVD method, for example. Further, an SiN film is formed on the TEOS film by use of the CVD method. After this, for example, an anisotropic etching process such as a RIE process, for example, is performed to etch a portion reaching the surface of the substrate 11. Thus, spacers 14 each formed of spacer insulating film 14-1, 14-2 are formed. Further, source/drain regions 15 are formed by the same manufacturing method as that for formation of the LDDs 30 with the dummy gate 29 and spacers 14 used as a mask.

Next, as shown in FIG. 8, silicide layers 16 are formed on the source/drain regions 15 by reacting the source/drain regions 15 with a refractory metal layer by use of a salicide process.

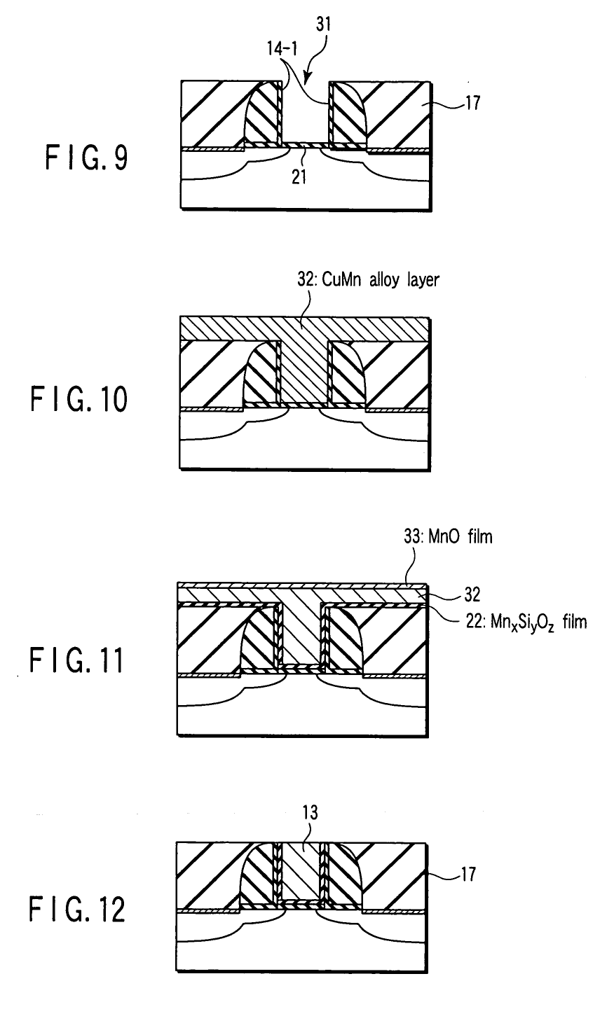

Then, as shown in FIG. 9, a silicon oxide film is deposited on the silicide layers 16, spacers 14 and dummy gate 29 to form an inter-level insulating film 17 by use of the CVD method, for example. After this, for example, the dummy gate 29 is removed by use of a wet etching method to form an opening which exposes the side walls of the spacer insulating films 14-1 and the upper surface of the insulating film 12.

As shown in FIG. 10, a CuMn (copper-manganese) alloy layer 32 is formed in the opening 31 and on the inter-level insulating film by use of a sputtering method or CVD method, for example.

Next, as shown in FIG. 11, for example, the heat treatment is performed for 30 min to 60 min at temperatures of 200° C. to 600° C. while the CuMn alloy layer 32 is kept set in contact with the insulating layer 12 and spacer insulating films 14-1. By the heat treatment, Mn elements in the CuMn alloy layer 32 are diffused to react with Si elements and O elements in the insulating layer 12 and spacer insulating films 14-1 to form uniform MnₓSi_{y}O_{z} films (ferroelectric films) 22-1, 22-2 with an extremely thin film thickness (2 nm to 3 nm) in a self-alignment fashion on the interfaces. Further, in the above process, surplus Mn reacts with oxygen O to form an MnO layer (oxidation reaction film) 33 on the surface of the CuMn alloy layer 32 by performing the heat treatment in an atmosphere containing oxygen.

The MnₓSi_{y}O_{z} films (ferroelectric films) 22-1, 22-2 formed in the above process have a feature that the film thickness thereof can be kept constant irrespective of the Mn concentration in the CuMn alloy layer 32. This is considered because Mn in the CuMn alloy layer 32 can take in no more oxygen (O) in the insulating film (SiO₂ film) 12 and the reaction process is stopped if the MnₓSi_{y}O_{z} films 22-1, 22-2 are uniformly formed.

Further, in the above reaction process, excessive Mn which is not used to form the MnₓSi_{y}O_{z} films 22-1, 22-2 reacts with oxygen in the heat treatment furnace. Then, most part of Mn precipitates on the surface of the CuMn alloy layer 32 without being solved in a solid state in the CuMn alloy layer 32 to form an MnO layer 33. When formation of the gate of the transistor TR1 is considered, the MnO layer 33 will not give an influence on the gate characteristic since it is removed in a later step. Further, even if a small amount of Mn is solved in a solid state in the CuMn alloy layer 32, the resistance of the gate electrode will not be markedly increased. Therefore, a sufficiently good characteristic of the gate electrode of the transistor TR1 can be attained.

It is possible to precipitate almost all of the Mn elements in the CuMn alloy layer 32 by suitably selecting the concentration of the Mn elements and reaction condition of the heat treatment. In this case, the gate electrode 13 can be formed of pure Cu.

Next, as shown in FIG. 12, for example, the extra MnO layer 33 is removed and the CuMn alloy layer 32 is polished and made flat to the surface of the inter-level insulating film 17 to form a gate electrode 13 by using a CMP (Chemical Mechanical Polishing) method.

After this, a contact wiring 19 is formed on the source/drain region 15 by use of a known manufacturing process to manufacture a semiconductor device shown in FIGS. 1 and 2.

According to the semiconductor device and the manufacturing method thereof according to the present embodiment, the following effects (1) to (5) are attained.

(1) It is advantageous in miniaturization:

As described above, the ferroelectric films (MnₓSi_{y}O_{z} films) 22-1, 22-2 are reaction-formed films which are formed by performing the heat treatment to diffuse Mn elements in the CuMn alloy layer 32 and react the Mn elements with Si elements and O elements in the insulating layer 12 and spacer insulating films 14-1 and which are formed in a self-alignment fashion on the interface.

Therefore, extremely thin (2 nm to 3 nm) and uniform ferroelectric films 22-1, 22-2 which are difficult to form in the film formation process of the conventional sputtering method or the like can be formed. As a result, since the gate insulating film 12 having a desired ferroelectric film 22-1 together with the insulating film 21 can be formed and the effective thickness thereof can be increased, it is advantageous in miniaturization.

It is confirmed that the ferroelectric films 22-1, 22-2 formed in the above step always have constant film thickness irrespective of the Mn concentration in the CuMn alloy layer 32 (FIG. 2). This is considered because Mn in the CuMn alloy layer 32 can take in no more oxygen (O) in the insulating film (SiO₂ film) 12 and the reaction process is stopped if the MnₓSi_{y}O_{z} films 22-1, 22-2 are uniformly formed.

Thus, the ferroelectric films 22-1, 22-2 are effective as the gate insulating film 12 because they can be formed with thin film thickness, uniform film quality and ferroelectricity.

(2) It is advantageous in manufacturing cost:

It is required for the gate insulating film to have thin film thickness and ferroelectricity according to the request for high performance of the LSI, but it becomes more difficult to select a material and select a film formation method as the gate insulating film is formed thinner. However, as described above, the ferroelectric films 22-1, 22-2 can be formed only by use of the heat treatment without using the film formation process (for example, sputtering method or CVD method).

Further, when the ferroelectric films 22-1, 22-2 are formed, a CuMn alloy can be used as a target in the sputtering process. Therefore, the conventional manufacturing apparatus for the sputtering process can be used as it is and it is not necessary to make an equipment investment for a new manufacturing apparatus. Thus, it is advantageous in the manufacturing cost.

(3) It is advantageous in lowering resistance of gate electrode 13:

At the time of the heat treatment for forming the ferroelectric films (MnₓSi_{y}O_{z} films) 22-1, 22-2, an MnO layer 33 is formed on the surface of a CuMn alloy layer 32. The MnO layer 33 is formed by causing extra Mn which is not used for formation of the MnₓSi_{y}O_{z} films 22-1, 22-2 to react with oxygen in the heat treatment furnace and precipitate on the surface of the CuMn alloy layer 32 without being solved in a solid state in the CuMn alloy layer 32.

Therefore, the purity of Cu in the CuMn alloy layer 32 which is left behind in the opening 31 and used as a material of the gate 13 is enhanced and the resistance thereof can be lowered in comparison with that before the heat treatment. As a result, the resistance of the gate electrode 13 can be reduced and it is advantageous in lowering the resistance.

Almost all of the Mn elements in the CuMn alloy layer 32 can be precipitated by adequately selecting the concentration of the Mn elements, reaction condition and time of the heat treatment. In this case, the gate electrode 13 can be formed of pure Cu.

Further, since the MnO layer 33 can be formed at the same time as the ferroelectric film 22, the number of manufacturing steps and manufacturing cost will not be increased.

(4) Reliability of gate electrode 13 formed of Cu or containing Cu as main component can be enhanced:

As described above, the gate electrode 13 is formed of Cu or the CuMn alloy layer 32 containing Cu as a main component.

In this case, Cu tends to mutually diffuse between surrounding insulating films and easily react with oxygen in an oxygen atmosphere to form a Cu oxide film. Therefore, it is necessary to form a diffusion barrier film of tantalum (Ta) or tantalum nitride (TaN) before forming a metal layer containing Cu as a main component. Particularly, when a buried Cu layer is formed in the inter-level insulating film as in the damascene structure of the present embodiment, diffusion of Cu into the insulating film becomes more significant and it is normally necessary to form a barrier film for diffusion.

However, in the case of the present embodiment, the CuMn alloy layer 32 reacts with the insulating layer 12 and spacer insulating films 14-1 to form ferroelectric films (MnₓSi_{y}O_{z} films) 22-1, 22-2 in a self-alignment fashion on the interfaces by performing the heat treatment. Thus, the ferroelectric films 22-1, 22-2 acting as barrier films which prevent diffusion of Cu in the gate electrode 13 can be simultaneously formed. As a result, diffusion of Cu in the gate electrode 13 can be prevented, electromigration by interface diffusion can be prevented and the reliability can be enhanced.

(5) It is effective in miniaturizing gate electrode 13 which is formed of Cu or contains Cu as a main component:

As described in the item (4), in the prior art, it is necessary for the diffusion barrier film to have a film thickness of 10 nm or more in order to attain the reliability of the gate electrode which contains Cu as a main component. Therefore, if an attempt is made to form the gate electrode which contains Cu as a main component, the area of the gate electrode is increased.

However, since the ferroelectric films 22-1, 22-2 acting as barrier films which prevent diffusion of Cu in the gate electrode 13 can be formed, the area of the barrier films can be reduced or the barrier films can be obviated (barrierless). Therefore, the occupied area of the barrier film can be reduced and it is effective to miniaturize the gate electrode 13.

If the barrier film is omitted, a gate electrode 13 containing Cu as a main component with the barrierless structure in which the barrier film forming process is completely omitted can be considered.

### Second Embodiment (One Example of Gate Electrode Formed by Etching)

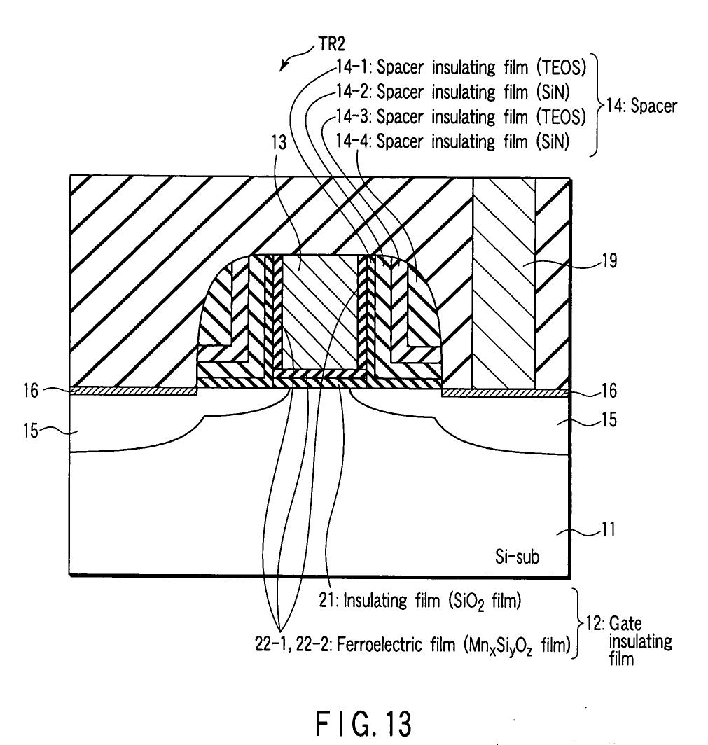

Next, a semiconductor device according to a second embodiment of this invention is explained with reference to FIG. 13. FIG. 13 is a cross sectional view showing the semiconductor device according to the second embodiment. The semiconductor device according to the second embodiment relates to a case wherein the etching process is used when the gate electrode 13 is formed. In the explanation, the explanation for portions which are the same as those of the first embodiment is omitted.

As shown in FIG. 13, the second embodiment is different from the first embodiment in that a transistor TR2 includes spacer insulating films 14-3, 14-4 in addition to the spacer insulating films 14-1, 14-2 and has the spacer 14 of a four-layered structure.

For example, the spacer insulating film 14-3 is formed of a TEOS film. The spacer insulating film 14-4 is formed of an SiN film, for example.

<Manufacturing Method>

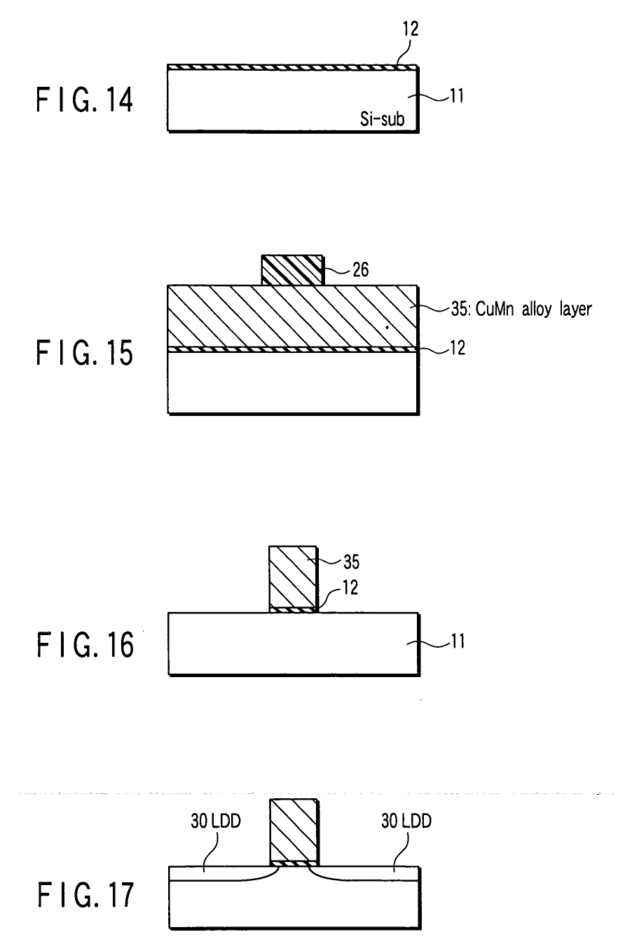

Next, the manufacturing method of the semiconductor device according to the second embodiment is explained with reference to FIGS. 14 to 20 by taking the semiconductor device of FIG. 13 as an example.

First, as shown in FIG. 14, for example, a silicon substrate 11 is heated to form a silicon oxide film (insulating film) 12 on the main surface of the substrate 11 by use of the thermal oxidation method.

Then, as shown in FIG. 15, a CuMn (copper-manganese) alloy layer 35 is formed on the silicon oxide film 12 by use of the sputtering method or CVD method, for example. After this, photoresist 26 is coated and the thus formed photoresist film 26 is subjected to the exposing and developing processes to form an opening which exposes the CuMn alloy layer 35.

Next, as shown in FIG. 16, for example, an anisotropic etching process such as an RIE process, for example, is performed to etch a portion reaching the surface of the substrate 11 with the photoresist film 26 having the opening used as a mask. Thus, the CuMn alloy layer 35 and insulating film 12 which configure a gate structure are left behind on the substrate 11.

Next, as shown in FIG. 17, an impurity of a conductivity type different from that of the substrate 11, for example, boron (B) or phosphorus (P) is doped into the substrate 11 by use of an ion-implantation method, for example, with the thus formed gate structure used as a mask. After this, the substrate 11 is heated to thermally diffuse the doped impurity to form LDDs 30.

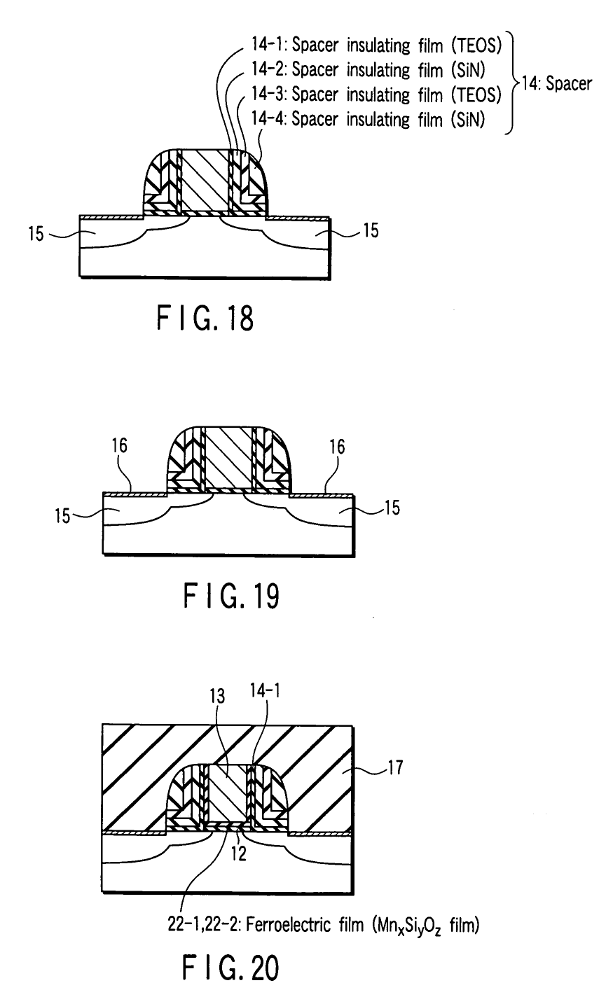

Then, as shown in FIG. 18, a TEOS film is formed on the substrate 11 and gate structure by use of the CVD method, for example. Next, an SiN film is formed on the TEOS film by use of the CVD method. Further, a TEOS film is formed on the SiN film by use of the CVD method. In addition, an SiN film is formed on the TEOS film by use of the CVD method. After this, for example, the anisotropic etching process such as the RIE process is performed to etch a portion reaching the surface of the substrate 11. Thus, spacers 14 each formed of an SiN film 14-4/TEOS film 14-3/SiN film 14-2/TEOS film 14-1 are formed.

Further, source/drain regions 15 are formed by the same manufacturing method as that for forming the LDDs 30 with the gate structure and spacers 14 used as a mask.

Next, as shown in FIG. 19, silicide layers 16 are formed on the source/drain regions 15 by reacting the source/drain regions 15 with a refractory metal layer by use of a salicide process.

Then, as shown in FIG. 20, the heat treatment is performed for 30 min to 60 min at temperatures of 200° C. to 600° C. while the CuMn alloy layer 32 is kept set in contact with the insulating layer 12 and spacer insulating films 14-1. By the heat treatment, Mn elements in the CuMn alloy layer 32 are diffused to react with Si elements and O elements in the insulating layer 12 and spacer insulating films 14-1 to form uniform and extremely thin (2 nm to 3 nm) MnₓSi_{y}O_{z} films (ferroelectric films) 22-1, 22-2 in a self-alignment fashion on the interfaces. Further, like the case described before, in the above process, an extra MnO layer (not shown) is formed on the surface of the CuMn alloy layer 32 which faces the insulating film 12.

The MnₓSi_{y}O_{z} films (ferroelectric films) 22-1, 22-2 formed in the above process have a feature that the film thickness thereof can always be kept constant irrespective of the Mn concentration in the CuMn alloy layer 35. This is considered because Mn in the CuMn alloy layer can take in no more oxygen (O) in the insulating film (SiO₂ film) 12 and the reaction process is stopped if the MnₓSi_{y}O_{z} films 22 are uniformly formed.

In this case, the above heat treatment process can be performed in a step before the step shown in FIG. 20. For example, the MnₓSi_{y}O_{z} films (ferroelectric films) 22-1, 22-2 are incidentally formed by the heat treatment performed at the time of formation of the source/drain regions 15 or at the time of the silicide layers 16 in some cases.

Next, for example, the extra MnO layer is removed to form a gate electrode 13 by use of the CMP method or the like.

After this, an inter-level insulating film 17 is formed to cover the gate electrode 13 and spacers 14 by use of a known process. Further, a contact wiring 19 is formed on the source/drain region 15 to manufacture the semiconductor device shown in FIG. 13.

According to the semiconductor device of the present embodiment and the manufacturing method thereof, the same effects as the effects (1) to (5) explained in the first embodiment can be attained.

Further, the transistor TR2 in the present embodiment further includes the spacer insulating films 14-3, 14-4 and has spacers 14 of the four-layered structure formed of the SiN film 14-4/TEOS film 14-3/SiN film 14-2/TEOS film 14-1.

Therefore, the spacer 14 can be prevented from being over-etched when the contact wiring 19 is formed and the insulating property of the spacer 14 can be enhanced.

[Modification 1]

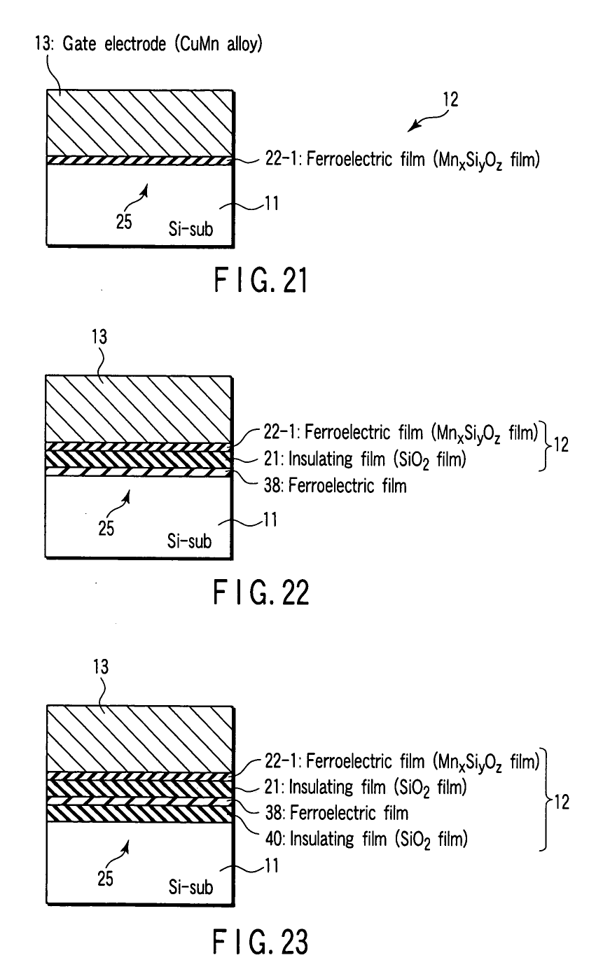

Next, a semiconductor device according to the modification 1 of this invention is explained with reference to FIG. 21. FIG. 21 is a cross sectional view showing a portion near the channel region 25 of the semiconductor device according to the modification 1. In this explanation, the explanation for portions which are the same as those of the first embodiment is omitted.

As shown in FIG. 21, the modification is different from the first embodiment in that the MnₓSi_{y}O_{z} film (ferroelectric film) 22-1 is formed on the interface between the semiconductor substrate 11 and the gate electrode 13 and only the ferroelectric film 22-1 acts as the gate insulating film.

The modification is different from the first embodiment in the following points in relation to the manufacturing method. That is, for example, the silicon substrate 11 is heated by use of the thermal oxidation method to form a silicon oxide film (insulating film) on the main surface of the substrate 11. In this process, by suitably selecting time and temperatures to heat the substrate 11, the film thickness of the silicon oxide film is controlled and set to the same film thickness (approximately 2 nm to 3 nm) of the ferroelectric film 22-1.

Then, a CuMn alloy layer is formed on the silicon oxide film by the same manufacturing process as that of the first embodiment.

After this, for example, the heat treatment is performed for 30 min to 60 min at temperatures of 200° C. to 600° C. while the CuMn alloy layer is kept set in contact with the silicon oxide film. Thus, Mn elements in the CuMn alloy layer are diffused to react with Si elements and O elements in the silicon oxide film to form a uniform MnₓSi_{y}O_{z} film (ferroelectric film) 22-1 with extremely thin film thickness (2 nm to 3 nm) in a self-alignment fashion on the interface.

In the heat treatment process, the film thickness of the silicon oxide film is controlled to have substantially the same film thickness (approximately 2 nm to 3 nm) as that of the ferroelectric film 22-1. Therefore, the reaction process which starts from the surface of the silicon oxide film proceeds to the surface of the substrate 11 and the ferroelectric film 22-1 which is integrally formed with the silicon oxide film can be formed. The other forming methods are substantially the same as those of the first embodiment.

According to the semiconductor device of the modification 1 and the manufacturing method thereof, the same effects as the effects (1) to (5) explained in the first embodiment can be attained.

Further, in the semiconductor device of the modification 1, only the ferroelectric film 22-1 is formed on the interface between the semiconductor substrate 11 and the gate electrode 13 and the insulating film 21 is not formed. Then, only the ferroelectric film 22-1 acts as the gate insulating film 12. Therefore, the film thickness of the gate insulating film 12 can be reduced and it is advantageous in miniaturization.

[Modification 2]

Next, a semiconductor device according to the modification 2 of this invention is explained with reference to FIG. 22. FIG. 22 is a cross sectional view showing a portion near the channel region 25 of the semiconductor device according to the modification 2. In this explanation, the explanation for portions which are the same as those of the first embodiment is omitted.

As shown in FIG. 22, the modification is different from the first embodiment in that the gate insulating film 12 includes a ferroelectric film 38 formed between the silicon substrate 11 and the insulating film (SiO₂ film) 21. The ferroelectric film 38 is formed of an SiN film (silicon nitride film), for example.

The modification is different from the first embodiment in the following points in relation to the manufacturing method. That is, for example, a ferroelectric material such as SiN is deposited on the substrate 11 by use of a film formation method such as the sputtering method or CVD method to form a ferroelectric film 38. The other forming methods are substantially the same as those of the first embodiment.

According to the semiconductor device and the manufacturing method thereof in the modification 2, the same effects as the effects (1) to (5) explained in the first embodiment can be attained.

The gate insulating film 12 further includes the ferroelectric film 38 formed between the silicon substrate 11 and the insulating film 21. Therefore, the dielectric constant of the whole portion of the gate insulating film 12 can be enhanced.

[Modification 3]

Next, a semiconductor device according to the modification 3 of this invention is explained with reference to FIG. 23. FIG. 23 is a cross sectional view showing a portion near the channel region 25 of the semiconductor device according to the modification 3. In this explanation, the explanation for portions which are the same as those of the first embodiment is omitted.

As shown in FIG. 23, the modification is different from the first embodiment in that the gate insulating film 12 further includes a ferroelectric film 38 and insulating film 40 formed between the silicon substrate 11 and the insulating film 21.

The modification is different from the first embodiment in the following points in relation to the manufacturing method. That is, for example, the silicon substrate 11 is heated by use of the thermal oxidation method or the like to form the silicon oxide film (insulating film) 40 on the main surface of the substrate 11.

Then, for example, a ferroelectric material such as SiN is deposited on the insulating film 40 by use of a film formation process such as the sputtering method or CVD method to form a ferroelectric film 38. The other forming methods are substantially the same as those of the first embodiment.

According to the semiconductor device and the manufacturing method thereof in the modification 3, the same effects as the effects (1) to (5) explained in the first embodiment can be attained.

Further, the gate insulating film 12 further includes the ferroelectric film 38 and insulating film 40 formed between the silicon substrate 11 and the insulating film 21. Therefore, the dielectric constant of the whole portion of the gate insulating film 12 can be enhanced.

### Third Embodiment (One Example of Nonvolatile Semiconductor Memory)

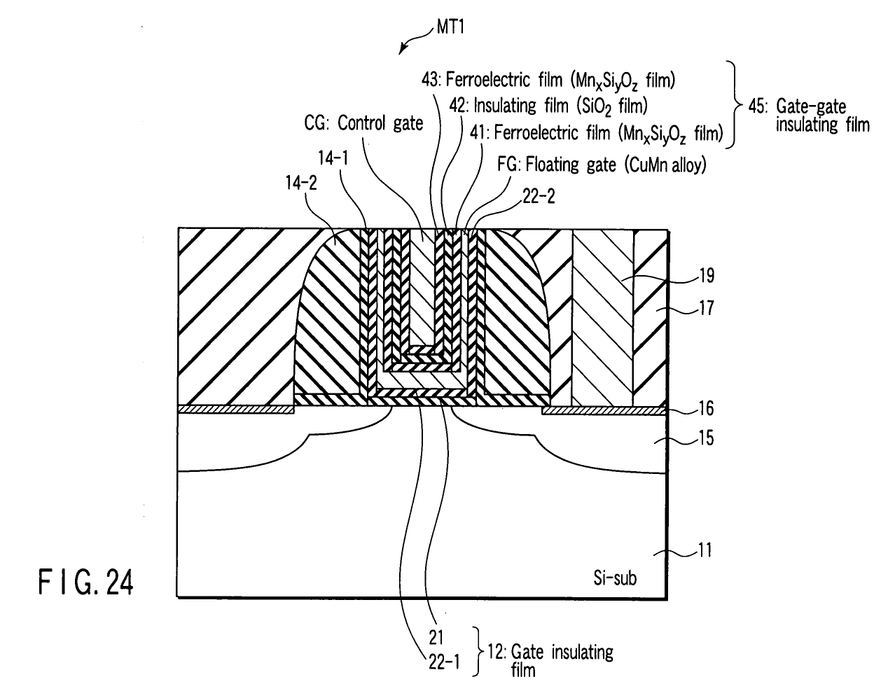

Next, a semiconductor device according to a third embodiment of this invention is explained with reference to FIG. 24. FIG. 24 is a cross sectional view showing the semiconductor device according to this embodiment. This embodiment relates to a case wherein the ferroelectric films 22-1, 22-2 are applied to so-called gate-gate insulating films of a nonvolatile semiconductor memory cell transistor MT1. In this explanation, the explanation for portions which are the same as those of the first embodiment is omitted.

As shown in FIG. 24, the third embodiment is different from the first embodiment in that a floating gate (floating electrode) FG is formed on the gate insulating film 12, a gate-gate insulating film (inter-gate insulating film) 45 is formed on the floating gate FG and a control gate (control electrode) CG is formed on the gate-gate insulating film 45.

The floating gate FG and control gate CG have a damascene metal gate structure formed of a CuMn alloy containing Cu as a main component.

The gate-gate insulating film 45 has a three-layered structure including a ferroelectric film 41 formed on the control gate CG, an insulating film 42 formed on the ferroelectric film 41 and a ferroelectric film 43 formed on the insulating film 42.

The ferroelectric films 41, 43 are formed of an MnₓSi_{y}O_{z} film. The insulating film 42 is formed of an SiO₂ film.

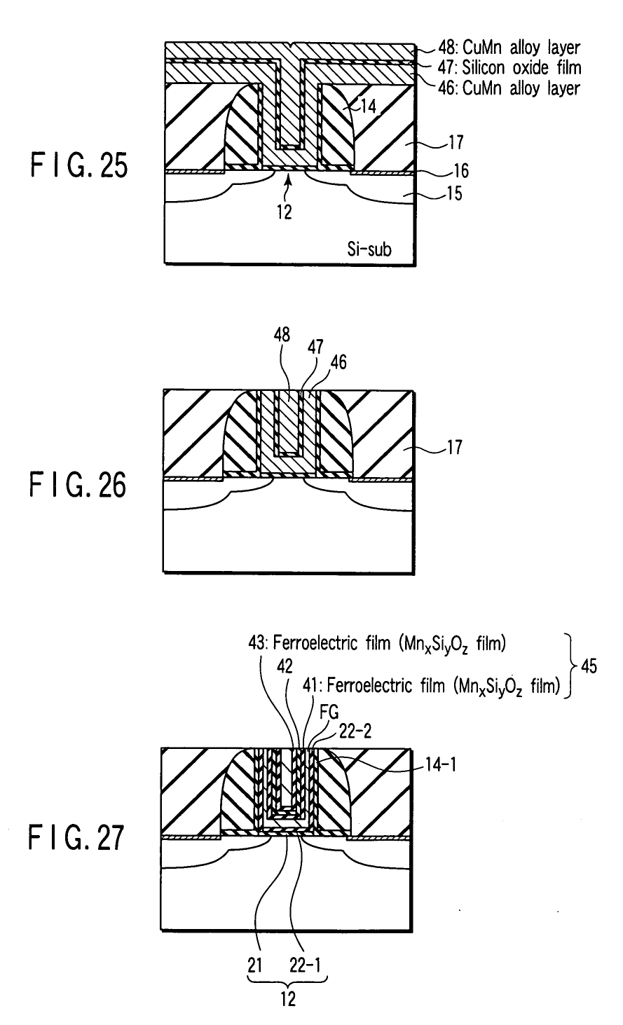

Next, the manufacturing method of the semiconductor device according to the present embodiment is explained with reference to FIGS. 25 to 27 by taking the semiconductor device shown in FIG. 24 as an example.

First, as shown in FIG. 25, for example, a gate insulating film 12, dummy gate (not shown), spacers 14, source/drain regions 15, silicide layers 16 and inter-level insulating film 17 are formed by use of the same manufacturing method (FIGS. 3 to 9) as that of the first embodiment. Then, the dummy gate is removed and an opening used to form a gate structure is formed in the inter-level insulating film 17.

After this, a CuMn alloy layer 46, SiO₂ film 47 and CuMn alloy layer 48 are sequentially deposited in the opening by use of the same manufacturing method as that of the first embodiment.

Next, as shown in FIG. 26, for example, the structure is polished to expose the inter-level insulating film 17 and is made flat by use of the CMP method. Thus, the CuMn alloy layer 46, SiO₂ film 47 and CuMn alloy layer 48 are embedded in the opening.

Then, as shown in FIG. 27, for example, the heat treatment is performed for 30 min to 60 min at temperatures of 200° C. to 600° C. with the SiO₂ film 47 disposed between the CuMn alloy layers 46 and 48. By the heat treatment, Mn elements in the CuMn alloy layer 46 are diffused to react with Si elements and O elements in the SiO₂ film 47. At the same time, Mn elements in the CuMn alloy layer 48 are diffused to react with Si elements and O elements in the SiO₂ film 47. Thus, uniform and extremely thin (2 nm to 3 nm) ferroelectric films (MnₓSi_{y}O_{z} films) 41, 43 are formed on the respective interfaces in a self-alignment fashion to form a gate-gate insulating film 45.

Further, by the above heat treatment, the ferroelectric film 22-1 is formed to form a gate insulating film 12 which acts together with the insulating film 21. The other forming methods are substantially the same as those of the first embodiment.

According to the semiconductor device and the manufacturing method thereof in the present embodiment, the same effects as the effects (1) to (5) explained in the first embodiment can be attained.

The gate-gate insulating film 45 has a three-layered structure including a ferroelectric film 41 formed on the control gate CG, an insulating film 42 formed on the ferroelectric film 41 and a ferroelectric film 43 formed on the insulating film 42. As explained above, since the ferroelectric films 41, 43 are formed of an MnₓSi_{y}O_{z} film, they can be formed with thin film thickness, uniform film quality and ferroelectricity. Therefore, when a voltage is applied to the control gate CG at the read/write operation time, the dielectric strength of the gate-gate insulating film 45 can be enhanced.

In addition, the ferroelectric films 41, 43 are reaction-formed films which are formed in a self-alignment fashion by causing them to react with the surfaces of the SiO₂ film 42 which are set in contact with them, that is, the upper and under surfaces thereof. Therefore, the film thickness of the gate-gate insulating film 45 is not increased just because the ferroelectric films 41, 43 are formed.

Further, the gate-gate insulating film 45 and gate insulating film 12 can be simultaneously formed by the heat treatment process. Therefore, the number of manufacturing steps can be reduced.

### Fourth Embodiment (One Example of Nonvolatile Semiconductor Memory)

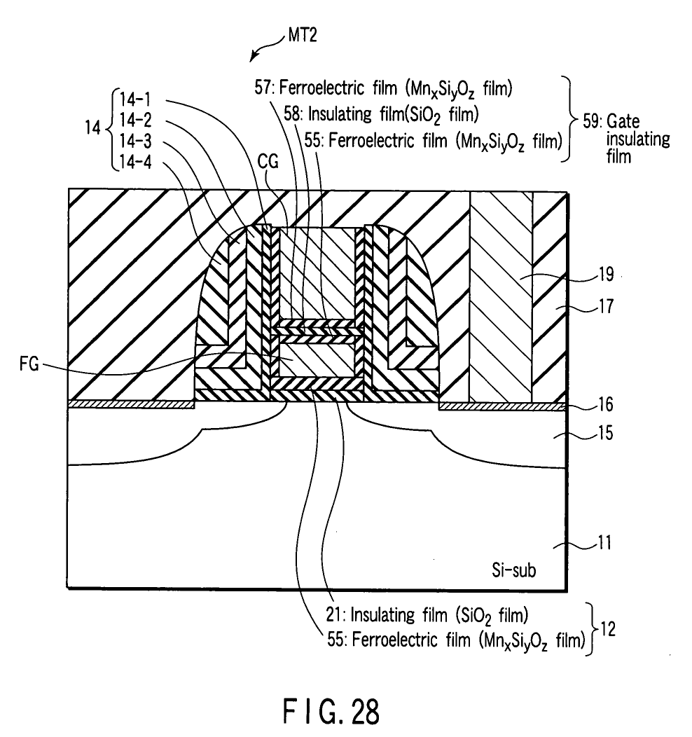

Next, a semiconductor device according to a fourth embodiment of this invention is explained with reference to FIG. 28. FIG. 28 is a cross sectional view showing the semiconductor device according to the present embodiment. The present embodiment relates to an etching gate structure in which the ferroelectric films 22-1, 22-2 are applied to a so-called gate-gate insulating film of a nonvolatile semiconductor memory cell transistor MT2. In this explanation, the explanation for portions which are the same as those of the third embodiment is omitted.

As shown in FIG. 28, the present embodiment is different from the third embodiment in the following points.

That is, a ferroelectric film (MnₓSi_{y}O_{z} film) 55 is formed along the periphery of a floating gate FG (on the interfaces between the floating gate FG and the insulating film 12, spacer insulating film 14-1 and insulating film 58).

Further, a ferroelectric film (MnₓSi_{y}O_{z} film) 57 is formed along the undersurface and side surfaces of a control gate CG (on the interfaces between the control gate CG and the insulating film 58 and spacer insulating film 14-1).

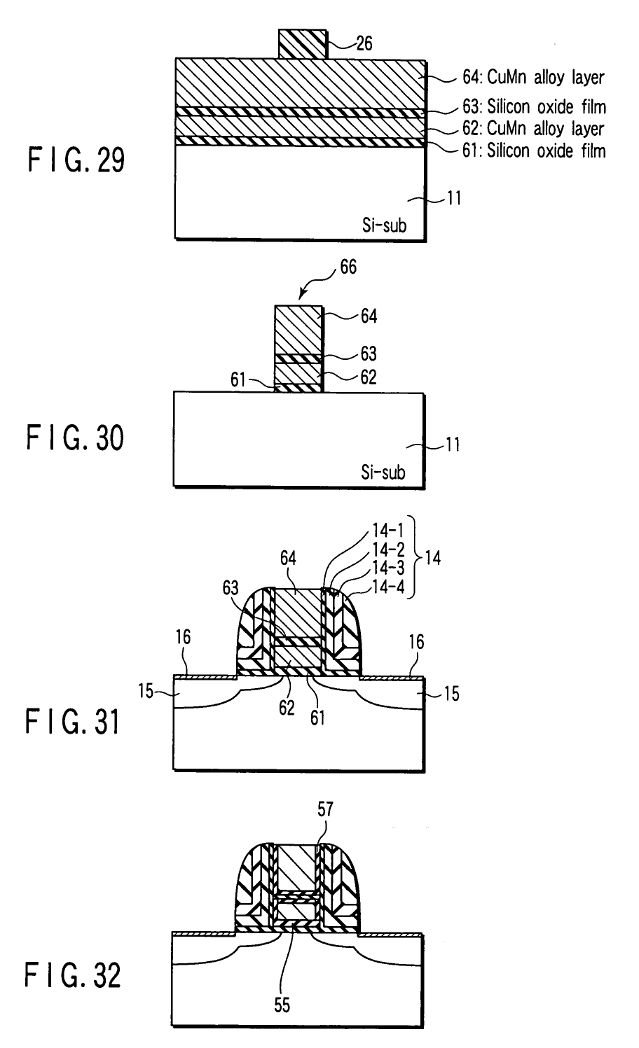

Next, a manufacturing method of the semiconductor device according to the present embodiment is explained with reference to FIGS. 29 to 32 by taking the semiconductor device shown in FIG. 28 as an example.

First, as shown in FIG. 29, for example, the silicon substrate 11 is heated by use of the thermal oxidation method or the like to form a silicon oxide film (insulating film) 61 on the main surface of the substrate 11. Then, a CuMn alloy layer 62 is formed on the silicon oxide film 61 by use of the plating method, for example. After this, a silicon oxide film 63 is formed on the CuMn alloy layer 62 by use of the CVD method, for example. Further, a CuMn alloy layer 64 is formed on the silicon oxide film 63 by use of the plating method, for example.

Next, photoresist 26 is coated on the CuMn alloy layer 64 and the thus formed photoresist film 26 is subjected to the exposing and developing processes to form an opening which exposes a gate structure forming area.

Then, as shown in FIG. 30, for example, the etching process such as the RIE process is performed with the photoresist film 26 used as a mask to form a gate structure 66 having a laminated structure of the silicon insulating films 61, 63 and CuMn alloy layers 62, 64 on the silicon substrate 11.

After this, as shown in FIG. 31, for example, a TEOS film is formed on the substrate 11 and gate structure 66 by use of the CVD method or the like. Further, an SiN film is formed on the TEOS film by use of the CVD method or the like, for example. Then, a TEOS film is formed on the SiN film by use of the CVD method. Further, an SiN film is formed on the TEOS film by use of the CVD method or the like, for example. Next, for example, the anisotropic etching process such as the RIE process is performed to etch a portion which reaches the surface of the substrate 11 so as to form spacers 14 each formed of an SiN film 14-4/TEOS film 14-3/SiN film 14-2/TEOS film 14-1.

After this, the same manufacturing process is performed to form source/drain regions 15 with the gate structure 66 and spacers 14 used as a mask.

Then, the salicide process is performed to react the source/drain regions 15 with a refractory metal layer so as to form silicide layers 16 on the source/drain regions 15.

Next, as shown in FIG. 32, the heat treatment is performed for 30 min to 60 min at temperatures of 200° C. to 600° C. while the CuMn alloy layer 62 is kept set in contact with the insulating film 61, spacer insulating films 14-1 and insulating film 63 and the CuMn alloy layer 64 is kept set in contact with the insulating film 63 and spacer insulating films 14-1. By the heat treatment, Mn elements in the CuMn alloy layer 62 are diffused to react with Si elements and O elements in the insulating film 61, spacer insulating films 14-1 and insulating film 63 to form a uniform MnₓSi_{y}O_{z} film (ferroelectric film) 55 with extremely thin film thickness (2 nm to 3 nm) in a self-alignment fashion on the interfaces. At the same time, by the above heat treatment, Mn elements in the CuMn alloy layer 64 are diffused to react with Si elements and O elements in the insulating film 63 and spacer insulating films 14-1 to form a uniform MnₓSi_{y}O_{z} film (ferroelectric film) 57 with extremely thin film thickness (2 nm to 3 nm) in a self-alignment fashion on the interfaces. The other forming methods are substantially the same as those of the first embodiment.

According to the semiconductor device and the manufacturing method thereof in the present embodiment, the same effects as the effects (1) to (5) explained in the first embodiment can be attained.

Further, the configuration and the manufacturing method of the present embodiment can be applied as required.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a gate insulating film which includes at least a first insulating film formed on the main surface of a semiconductor substrate and a first ferroelectric film formed on the first insulating film, containing a compound of a preset metal element and a constituent element of the first insulating film as a main component and having a dielectric constant larger than that of the first insulating film,
a gate electrode formed on the gate insulating film and formed of one of Cu and a material containing Cu as a main component, and
source and drain regions separately formed in the semiconductor substrate to sandwich the gate electrode.

2. The semiconductor device according to claim 1, wherein the gate insulating film further includes a second insulating film between the semiconductor substrate and the first insulating film.

3. The semiconductor device according to claim 1, further comprising spacers formed on side walls of the gate electrode, the spacers including first spacer insulating films formed on the semiconductor substrate and the side walls of the gate electrode, and second ferroelectric films formed on interfaces between the gate electrode and the first spacer insulating films, containing a compound of a preset metal element and a constituent element of the first spacer insulating film as a main component and having a dielectric constant larger than that of the first spacer insulating film.

4. The semiconductor device according to claim 3, wherein each of the spacers further includes a second spacer insulating film formed on the first spacer insulating film, a third spacer insulating film formed on the second spacer insulating film and formed of the same insulating material as that of the first spacer insulating film, and a fourth spacer insulating film formed on the third spacer insulating film and formed of the same insulating material as that of the second spacer insulating film.

5. The semiconductor device according to claim 1, further comprising silicide layers formed on the source and drain regions, an inter-level insulating film formed to cover the gate electrode, spacers and silicide layers, and a contact wiring formed in the inter-level insulating film and electrically connected to one of the source and drain regions.

6. The semiconductor device according to claim 3, wherein the preset metal element contains at least one element selected from a group consisting of Mn, Nb, Zr, Cr, V, Y, Tc and Re, the first insulating film and first spacer insulating film contain an O element and at least one element selected from a group consisting of Si, C and F, and the first and second ferroelectric films contain a material selected from a group consisting of αₓO_{y}, αₓSi_{y}O_{z}, αₓC_{y}O_{z} and αₓF_{y}O_{z} as a main component, α indicating the preset metal element.

7. A semiconductor device comprising:
a gate insulating film which at least includes a first insulating film formed on the main surface of a semiconductor substrate and a first ferroelectric film formed on the first insulating film, containing a compound of a preset metal element and a constituent element of the first insulating film as a main component and having a dielectric constant larger than that of the first insulating film,
a floating electrode formed on the gate insulating film and formed of one of Cu and a material containing Cu as a main component,
source and drain regions separately formed in the semiconductor substrate to sandwich the floating electrode,
a gate-gate insulating film which at least includes a second insulating film formed on the floating electrode and a second ferroelectric film formed on the second insulating film, containing a compound of a preset metal element and a constituent element of the second insulating film as a main component and having a dielectric constant larger than that of the second insulating film, and
a control electrode formed on the gate-gate insulating film and formed of one of Cu and a material containing Cu as a main component.

8. The semiconductor device according to claim 7, wherein the gate-gate insulating film further includes a third ferroelectric film formed on an interface between the floating electrode and the second insulating film, containing a compound of a preset metal element and a constituent element of the first spacer insulating film as a main component and having a dielectric constant larger than that of the second insulating film.

9. The semiconductor device according to claim 7, further comprising spacers formed on the floating electrode and side walls of the control electrode, the spacers including first spacer insulating films formed on the semiconductor substrate, floating electrode and the side walls of the control electrode, and third ferroelectric films formed on interfaces between the floating electrode and the first spacer insulating films, containing a compound of a preset metal element and a constituent element of the first spacer insulating film as a main component and having a dielectric constant larger than that of the first spacer insulating film.

10. The semiconductor device according to claim 9, further comprising fourth ferroelectric films formed on interfaces between the control electrode and the first spacer insulating films, containing a compound of a preset metal element and a constituent element of the first spacer insulating film as a main component and having a dielectric constant larger than that of the first spacer insulating film.

11. The semiconductor device according to claim 9, wherein each of the spacers further includes a second spacer insulating film formed on the first spacer insulating film, a third spacer insulating film formed on the second spacer insulating film and formed of the same insulating material as that of the first spacer insulating film, and a fourth spacer insulating film formed on the third spacer insulating film and formed of the same insulating material as that of the second spacer insulating film.

12. The semiconductor device according to claim 7, further comprising silicide layers formed on the source and drain regions, an inter-level insulating film formed to cover the gate electrode, spacers and silicide layers, and a contact wiring formed in the inter-level insulating film and electrically connected to one of the source and drain regions.

13. The semiconductor device according to claim 10, wherein the preset metal element contains at least one element selected from a group consisting of Mn, Nb, Zr, Cr, V, Y, Tc and Re, the first and second insulating films and first spacer insulating film contain an O element and at least one element selected from a group consisting of Si, C and F, and the first to fifth ferroelectric films contain a material selected from a group consisting of αₓO_{y}, αₓSi_{y}O_{z}, αₓC_{y}O_{z} and αₓF_{y}O_{z} as a main component, α indicating the preset metal element.

14. A method of manufacturing a semiconductor device comprising:
forming a first insulating film on the main surface of a semiconductor substrate,
forming a dummy gate on the insulating film,
doping impurity into the semiconductor substrate to form source and drain regions with the dummy gate used as a mask,
forming spacer insulating films on side walls-of the dummy gate,
removing the dummy gate to form an opening which exposes the surface of the first insulating film,
forming an electrode layer which contains a preset metal element and contains Cu as a main component in the opening, and
performing heat treatment to form a first ferroelectric film which contains a compound of the preset metal element and a constituent element of the first insulating film as a main component and having a dielectric constant larger than that of the first insulating film on an interface between the first insulating film and the electrode layer in a self-alignment fashion.

15. The method of manufacturing a semiconductor device according to claim 14, wherein the forming the electrode layer includes:
forming a second insulating film in the opening along the electrode layer, and
forming an alloy film which contains a preset metal element and contains Cu as a main component in the opening along the second insulating film,
the heat treatment including forming a second ferroelectric film which contains a compound of the preset metal element and a constituent element of the second insulating film as a main component and has a dielectric constant larger than that of the second insulating film on an interface between the second insulating film and the alloy film in a self-alignment fashion.

16. The method of manufacturing a semiconductor device according to claim 14, wherein the heat treatment includes forming a second ferroelectric film which contains a compound of the preset metal element and a constituent element of the spacer insulating film as a main component and has a dielectric constant larger than that of the spacer insulating film on an interface between the spacer insulating film and the electrode layer in a self-alignment fashion.

17. The method of manufacturing a semiconductor device according to claim 14, wherein the heat treatment includes forming a reaction film obtained as a result of reaction between an excessive portion of the preset metal element and the outside air on the surface of the electrode layer.
